(19) United States
(12) Patent Application Publication
(10) Pub. No.: US 2005/0117203 A1
(43) Pub. Date: Jun. 2, 2005

(54) Method for producing an optical element from a quartz substrate

(75) Inventors: Nils Dieckmann, Huettlingen (DE); Kirstin Becker, Aalen (DE); Dieter Bader, Goeggingen (DE)

Correspondence Address: WELSH & KATZ, LTD, 120 S RIVERSIDE PLAZA, 22ND FLOOR, CHICAGO, IL, 60606, US

(73) Assignee: Carl Zeiss SMT AG, Oberkochen (DE)

(21) Appl. No.: 10/985,488

(22) Filed: Nov. 10, 2004

Related U.S. Application Data
(63) Continuation of application No. 10/423,813, filed on Apr. 25, 2003.

(30) Foreign Application Priority Data
May 4, 2002 (DE) 102 20 045.9

(51) Int. Cl. G03B 27/54; G03B 27/72; G02B 1/00; G02B 5/18; G02B 27/42; G02B 5/02; G02B 13/20; G03F 7/20; G03F 7/40

(52) U.S. Cl. 359/350; 359/558; 359/599; 430/321

(57) ABSTRACT

In a method for producing an optical element from a quartz substrate for illumination systems with illumination sources which emit beams of wavelength 157 nm or shorter, the quartz substrate is joined to a support body on at least one side. Subsequently, from the quartz substrate material is removed to a desired value with a thickness in the μ region. The optical element can be a diffractive optical element or diffusion plate.

### BACKGROUND OF THE INVENTION

1. Field of the Invention

The invention relates to a method for producing an optical element from a quartz substrate for illumination systems with illumination sources which emit very shortwave beams, in particular of wavelength 157 nm or shorter.

The invention also relates to a projection exposure machine with an illumination system for microlithography for producing semiconductor elements.

2. Description of the Related Art

In illumination systems for the photolithographic patterning process of semiconductor components, it is known to set the illumination in the illuminating pupil by means of diffractive optical elements (DOE), which introduce diffraction effects to the beam. For this purpose, the latter are installed in the illumination system of the projection exposure machine at appropriate points. For the diffractive optical elements, it is known for these elements, in which an appropriate surface pattern is introduced, to be produced from quartz glass or quartz substrate in illumination systems which operate in the deep UV region.

Moreover, for the purpose of homogenization of the pupil, use is made in illumination systems of the above-named type of diffusion screen or plate which likewise consist of a quartz substrate. Diffusion plates introduce statistical divergence distributions.

However, owing to the use of light sources with ever shorter wavelengths, a problem arises with the use of quartz substrate. In particular, quartz substrate is no longer sufficiently stable in the case of radiation with light of wavelength 157 nm or shorter. For this reason, it is necessary in the case of such short wavelengths to produce diffractive optical elements or diffusion screens or plates from a material which, firstly, is transparent and, secondly, is resistant to these short wavelengths. Calcium fluoride (CaF₂), inter alia, is known for this purpose. However, it is disadvantageous in this connection that the production of a diffractive optical element or a diffusion screen or plate from calcium fluoride is very complicated and expensive.

### SUMMARY OF THE INVENTION

It is therefore the object of the present invention to create a method for producing an optical element, in particular a diffractive optical element or a diffusion screen or plate for use in light sources with very short wave variation, which element can be produced without complicated production methods.

According to the invention this object is achieved by means of a method for producing an optical element from a quartz substrate for illumination systems having light sources which emit beams of a very short wavelength, in particular of wavelength 157 nm or shorter, the quartz substrate being joined on at least one side to a support body and subsequently material from the quartz substrate is removed to a desired value with a thickness in the μ region.

Removal material by any method as grinding, polishing, etching, ruling ablating or others are included in the scope of the invention.

The inventors have surprisingly recognized that despite the inherently inadequate stability of quartz substrate (quartz glass), the latter can still be used for a wavelength of 157 nm or shorter if it is appropriately produced in the inventive way to be very thin. In this case, no problems arise with the stability, and the radiation losses otherwise occurring when a quartz substrate is used can likewise be neglected given this thickness.

However, given a desired thickness of the quartz substrate layer in the μ region, it is not possible to produce an unsupported optical element, for example a diffractive optical element or a diffusion screen or plate. Consequently, there is created in a way according to the invention a carrier for the thin quartz substrate which must, of course, be resistant to a wavelength region provided and must be transparent if it is to remain on the optical element. Calcium fluoride was provided as substrate for this purpose, and can be wrung onto the quartz substrate in one refinement of the invention.

During the production of a diffractive optical element into which a surface pattern is introduced, the said element will be provided in a first method step with a support body on the side of the diffractive optical element into which the surface pattern is introduced. Subsequently, the diffractive optical element, which consists, after all, of quartz substrate, is ablated to the desired value, something which can be performed, for example, by lapping and polishing. Finally, a carrier is mounted, for example wrung, onto the thinly ground quartz substrate, after which the support body is released from the quartz substrate.

During the production of a diffusion screen or plate, a quartz substrate which is subsequently ground down in each case to the desired value is mounted on both sides of the support body. For the purpose of forming a diffusion screen or plate, the profilings are then etched into the surfaces of the two very thin quartz layers created in this way. Since in this case the support body serves at the same time as carrier for the later use as diffusion screen or plate of the unit created in this way, it is necessary for it to consist of a material which is resistant to the wavelength used, for example of 157 nm or shorter, and is transparent.

Advantageous refinements and developments of the invention emerge from the remaining subclaims and from the exemplary embodiment described below in principle with the aid of the drawing.

### BRIEF DESCRIPTION OF THE DRAWINGS

FIG. 1 shows a schematic illustration of a projection exposure machine with an illumination system;

FIGS. 2 to 5 show the production of a diffractive optical element;

FIG. 6 and FIG. 7 show the production of a diffusion screen or plate.

### DETAILED DESCRIPTION

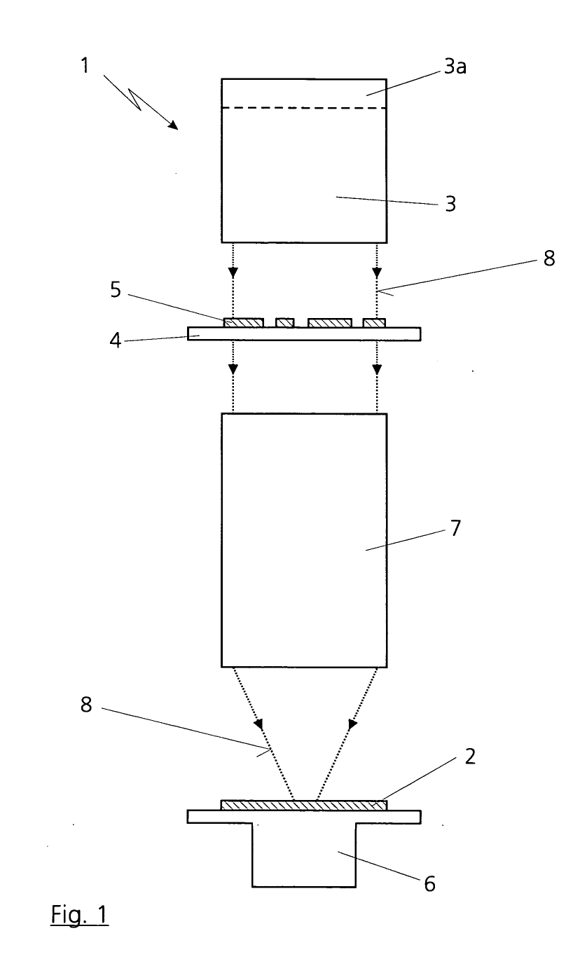

A projection exposure machine 1 for microlithography is illustrated in FIG. 1. The said machine serves for exposing patterns onto a substrate, coated with photosensitive materials and which consists in general largely of silicon and is denoted as a wafer 2, for producing semiconductor components such as, for example, computer chips.

The projection exposure machine 1 consists in this case essentially of an illumination device 3 with a light source 3a (not illustrated in more detail), a device 4 for holding and exactly positioning a mask provided with a grate-like pattern, a so-called reticle 5, by means of which the later patterns are determined on the wafer 2, a device 6 for holding, moving and exactly positioning this very wafer 2, and an imaging device, specifically a projection objective 7.

The basic functional principle provides in this case that the patterns introduced into the reticle 5 are exposed onto the wafer 2, in particular with a downscaling of the patterns to a third or less of the original size. The requirements to be made of the projection exposure machine 1, in particular of the projection objective 7, with regard to the resolutions reside in this case in the region of a few nanometers. After exposure has been performed, the wafer 2 is moved on such that a multiplicity of individual fields, in each case having the pattern prescribed by the reticle 5 are exposed onto the same wafer 2. Once the entire surface of the wafer 2 is exposed, the latter is removed from the projection exposure machine 1 and subjected to a plurality of chemical processing steps, in general an etching ablation of material. If appropriate, a plurality of these exposure and processing steps are carried out one after another until a multiplicity of computer chips are produced on the wafer 2. The projection exposure machine 1 is frequently also designated as a stepper because the wafer 2 is advanced in it in a stepwise fashion.

The illumination device 3 provides a projection beam 8 required for imaging the reticle 5 onto the wafer 2, for example light or a similar electromagnetic radiation. A laser or similar can be used as light source 3a for this radiation. The radiation is formed in the illumination device 3 via optical elements such that when impinging on the reticle 5 the projection beam 8 has the desired properties with regard to diameter, polarization, shape of the wave front and the like.

Via the projection beam 8, an image of the reticle 5 is generated and transmitted onto the wafer 2 by the projection objective 7 in a correspondingly scaled down fashion, as has already been explained above. The projection objective 7 in this case consists of a multiplicity of individual refractive and/or diffractive optical elements such as, for example, diffusion screens or plates, mirrors, prisms, end plates and the like.

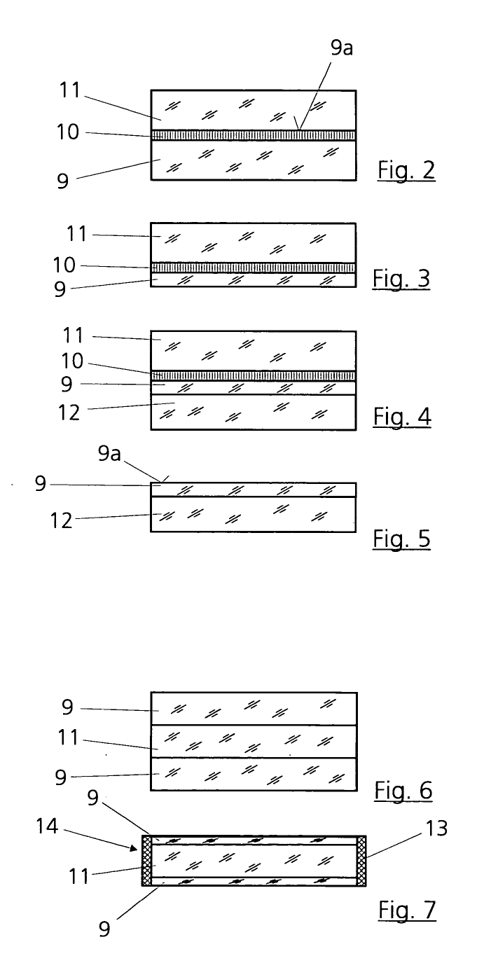

FIGS. 2 to 7 show the production of optical elements which can be parts of such a projection exposure machine 1.

Diffractive optical elements and diffusion screens or plates are arranged in a known way in the illumination system 3, in which the light source 3a, which emits beams with a wavelength of 157 nm or shorter is arranged.

The production of a diffractive optical element from a quartz substrate 9 is shown in FIGS. 2 to 5.

In accordance with FIG. 2, the quartz substrate 9 is mounted at a thickness of several millimeters on a support body 11 via an adhesive layer 10. A quartz substrate 9 can likewise be used as support body 11 for the following ablation method. The adhesive layer 10 is mounted on the side of the quartz substrate 9 in which the surface pattern 9a has already been introduced.

The ablation method for the quartz substrate 9 can be performed in a first step by lapping and in a second step by polishing down to the desired value in the μ region. The desired value thickness can be, for example, 5 to 10μ in the case of a use as DOE.

The quartz substrate 9 is illustrated in FIG. 3 with the desired value after the ablation method. However, the thickness of the quartz substrate 9 has been illustrated in a greatly exaggerated fashion for illustrative reasons.

In a next step, which is illustrated in FIG. 4, a carrier 12 is mounted on the ablated side of the quartz substrate 9. This can be performed, for example, by wringing with the aid of surfaces of appropriate high optical precision. The carrier 12, which must be resistant to beams of wavelength 157 nm and be transparent, can consist of calcium fluoride. Such a wringing method is disclosed, for example, in DE 197 04 936 A1 and in U.S. Pat. No. 4,810,318.

After the wringing of the carrier 12 onto the quartz substrate 9, the support body 11 with the adhesive layer 10 is released from the side of the quartz substrate 9 with the surface pattern 9a, as a result of which a finished diffractive optical element made from a quartz substrate with a thickness of a few μ is present. The carrier 12 serves for the required stability and for joining to a fixed structure of the illumination system 3. A thermal cement, such as canada balsam, can be used as removable adhesive 10. The cement itself can have a slight wedge.

In order for it to be possible to maintain a uniform layer thickness during the ablation method performed in the quartz substrate 9, it is to be ensured that during the ablation method the support body 11 is set with its rear side exactly parallel to the side of the quartz substrate 9 to be processed. The ablation method by lapping can be performed down to a thickness of approximately 15 to 20μ greater than the desired thickness. The ablation down to the desired thickness is performed subsequently by polishing in an iterative process in combination with thickness measurements. In the case of the use of a thermal adhesive, the bonded joint with the support body 11 can be released by appropriately heating after the ablation method and the wringing of the carrier 12, it also then being possible to remove the remnants of adhesive completely on the surface pattern 9a of the diffractive optical element.

The production of a diffusion screen or plate 14 is illustrated in FIGS. 6 and 7. In accordance with FIG. 6, a quartz substrate 9 of usual thickness, for example, a few millimeters, is mounted on both sides of the support body 11. Subsequently, the two quartz substrates 9 are respectively ablated down to the desired value. The finished thickness is to be seen from FIG. 7, here, as well, the thickness of the two quartz substrates 9 being represented substantially larger for illustrative reasons.

Since the support body 11 serves simultaneously in this case as carrier for the later diffusion screen or plate, it must consist of a material which is resistant to the beams of the light source 3a, for example of wavelength 157 nm or shorter, and is transparent. Calcium fluoride is used for this purpose in the exemplary embodiment. After the ablation of the two quartz substrates 9 down to the desired values, which can be between 40 and 70μ, preferably approximately 50μ, in the case of use as diffusion screen or plate, the desired surface profiling is performed in a known way by means of an etching method in order to form a diffusion screen or plate. This can, as is known, be performed in a simple way by means of an etch bath. Since the carrier 11 of calcium fluoride would, however, be modified negatively by the etch bath, the entire unit of support body 11 or carrier and the two quartz substrates 9 is provided in advance with a seal 13 at the circumference. The support body or carrier 11 is protected appropriately in this way in the case of an etch bath.

1-22. (canceled)

23. An optical element which consists of a quartz substrate at least 10μ thick, and which is arranged on a carrier, which is resistant to very short wave, beams and is transparent.

24. Optical element according to claim 23, wherein said carrier is resistant to a wavelength of 157 nm or shorter.

25. Optical element according to claim 23, wherein said optical element is a diffractive optical element into which a surface structure is introduced.

26. Optical element according to claim 23, wherein said optical element is a diffusion plate.

27. Optical element according to claim 23, wherein said optical element is a lens.

28. Optical element according to claim 23, wherein said optical element is an end plate.

29. Optical element according to claim 23, wherein said carrier contains calcium fluoride.

30. Optical element according to claim 23, wherein said optical element is an end plate and wherein said carrier contains calcium fluoride.

31. Optical element according to claim 23, wherein said optical element is a lens and wherein said carrier contains calcium fluoride.

32. A method for producing an optical element made from a quartz substrate, wherein said quartz substrate being joined on at least one side to a support body and subsequently material is removed to a desired value with a thickness in the μ region.

33. The Method according to claim 32, wherein said light sources emit beams of wavelength 157 nm or shorter.

34. The Method according to claim 32 for producing a diffractive optical element from a quartz substrate, into which a surface structure is introduced, wherein said support body is joined to said quartz substrate on the side of said diffractive optical element into which said surface structure is introduced, wherein subsequently said quartz substrate ablated to a desired value is mounted on a carrier, and wherein, finally, said quartz substrate is released from said support body.

35. The method according to claim 34, wherein said quartz substrate ablated to a desired value is mounted on a carrier which is resistant to a radiation of wavelength 157 nm or shorter and is transparent.

36. The Method according to claim 34, wherein said support body is joined to said quartz substrate via a removable adhesive layer.

37. Method according to claim 34, wherein said quartz glass is used as support body.

38. The Method according to claim 34, wherein said side of support body on the side averted from said quartz substrate is held parallel to the face of said quartz substrate to be processed.

39. The Method according to claim 32, wherein the ablation of said quartz substrate is performed in a first step by lapping and in a second step by polishing down to the desired value.

40. The Method according to claim 34, wherein calcium fluoride is used as carrier.

41. The Method according to claim 32 for producing a diffusion plate, wherein said support body is joined on both sides to quartz substrates, said support body which acts as carrier after the ablation of the two quartz substrates to their desired value, being resistant to a radiation of said light source and being transparent.

42. The Method according to claim 41, wherein said calcium fluoride is used as support body.

43. The Method according to claim 41, wherein said support body is wrung onto both sides of said quartz substrates.

44. The Method according to claim 41, wherein said support body as carrier with the quartz substrate mounted on both sides, is provided at the circumference with a seal.

45. The Method according to claims 41, 42, 43 or 44 wherein the unit formed from the support body and the two quartz substrates is etched to form said diffusions plate.

46. The method according to claim 45, wherein the etching is performed in an etch bath.

47. Projection exposure machine including an illumination system for microlithography, for producing semiconductor elements, and a projection objective with one or more optical elements which have a quartz substrate and are respectively mounted at thickness in the μ region on a carrier which is resistant to beams from a light source of the machine and is transparent.

48. Projection exposure machine according to claim 47, wherein said optical element is a diffractive optical element into which a surface structure is introduced.

49. Projection exposure machine according to claim 47, wherein said optical element is a diffusion plate.

50. Projection exposure machine according to claim 47, wherein said optical element is a lens.

51. Projection exposure machine according to claim 47, wherein said optical element is an end plate.

52. Projection exposure machine according to claim 47, wherein said carrier contains calcium fluoride.

53. Projection exposure machine according to claim 47, wherein said optical element is an end plate and wherein said carrier contains calcium fluoride.

54. Projection exposure machine according to claim 47, wherein said optical element is a lens and wherein said carrier contains calcium fluoride.
